(19) United States
(12) Patent Application Publication
(10) Pub. No.: US 2005/0007094 A1
(43) Pub. Date: Jan. 13, 2005

(54) Two wire hall device output detection circuit

(76) Inventor: John P. Hill, Hazel Park, MI (US)

Correspondence Address: Jeremy J. Curcuri;Brooks & Kushman P.C., 22nd Floor, 1000 Town Center, Southfield, MI, 48075-1351, US

(21) Appl. No.: 10/218,973

(22) Filed: Aug. 13, 2002

(51) Int. Cl. G01R 22/00

(52) U.S. Cl. 324/117 H

(57) ABSTRACT

A two wire Hall device output detection circuit includes a differential amplifier, a current mirror, and an output stage amplifier. The current mirror has a reference side and an output side, and is connected across a differential output of the differential amplifier. The output stage amplifier has an input connected to the output side of the current mirror, and an output.

### BACKGROUND OF THE INVENTION

1. Field of the Invention

The present invention relates to two wire Hall devices, and two wire Hall device output detection circuits.

2. Background Art

A Hall effect device produces an output when exposed to a magnetic field. Within the device, a current carrying conductor is exposed to the magnetic field and a Hall voltage is produced. In any suitable way, the presence or absence of a significant Hall voltage is indicated at the Hall effect device output. There are a number of existing two wire Hall devices. A detection circuit connected to the Hall device output detects the device output and provides an amplified output typically by using operational amplifiers. Operational amplifiers are expensive and circuits using them have a limited supply voltage range. Existing Hall effect related devices are described in U.S. Pat. Nos. 4,645,950; 5,218,298; 4,374,333; 4,134,030; 5,694,040; 5,619,137; 5,570,034; 5,500,585; 5,659,249; and 4,833,406.

### SUMMARY OF THE INVENTION

For the foregoing reasons, there is a need for an improved two wire Hall device output detection circuit.

It is, therefore, an object of the present invention to provide an improved two wire Hall device output detection circuit that utilizes a differential amplifier and a current mirror.

In carrying out the above object, a two wire Hall device output detection circuit is provided. The circuit comprises a differential amplifier, a current mirror, and an output stage amplifier. The differential amplifier includes a differential input and a differential output. The current mirror has a reference side and an output side. The current mirror is connected across the differential output of the differential amplifier. The output stage amplifier has an input connected to the output side of the current mirror, and an output.

In a preferred embodiment, the differential amplifier includes a pair of bipolar junction transistors in a common emitter configuration with collector outputs. The current mirror includes a pair of bipolar junction transistors with collectors connected to the collector outputs of the differential amplifier. The output stage amplifier includes a bipolar junction transistor with a base input and a collector output.

Further, in carrying out the present invention, in combination with a two wire Hall device, a two wire Hall device output detection circuit is provided. The circuit comprises a differential amplifier, a current mirror, and an output stage amplifier. The differential amplifier includes a differential input and a differential output. The differential input is connected across the two wire Hall device. The current mirror has a reference side and an output side. The current mirror is connected across the differential output of the differential amplifier. The output stage amplifier has an input connected to the output side of the current mirror, and an output.

In a preferred embodiment, the differential amplifier includes a pair of bipolar junction transistors in a common emitter configuration with collector outputs. The current mirror includes a pair of bipolar junction transistors with collectors connected to the collector outputs of the differential amplifier. The output stage amplifier includes a bipolar junction transistor with a base input and a collector output.

The above object and other objects, features, and advantages of the present invention are readily apparent from the following detailed description of the preferred embodiment when taken in connection with the accompanying drawings.

### BRIEF DESCRIPTION OF THE DRAWINGS

FIG. 1 illustrates a block diagram of a two wire Hall device output detection circuit connected to a two wire Hall device in accordance with the present invention; and

FIG. 2 illustrates a preferred embodiment of a two wire Hall device output detection circuit of the present invention connected to a circuit model of a two wire Hall device.

### DETAILED DESCRIPTION OF THE PREFERRED EMBODIMENT

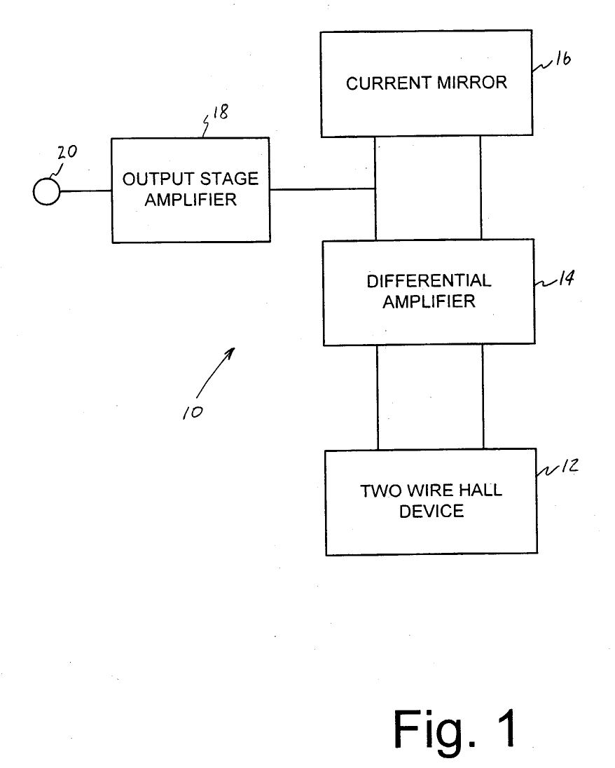

FIG. 1 illustrates a two wire Hall device output detection circuit and a two wire Hall device, generally, at 10. A two wire Hall device 12 is connected across a differential input of a differential amplifier 14. Differential amplifier 14 has a differential output. A current mirror 16 has a reference side and an output side, and is connected across the differential output of differential amplifier 14. An output stage amplifier 18 has an input connected to the output side of current mirror 16 and an output 20.

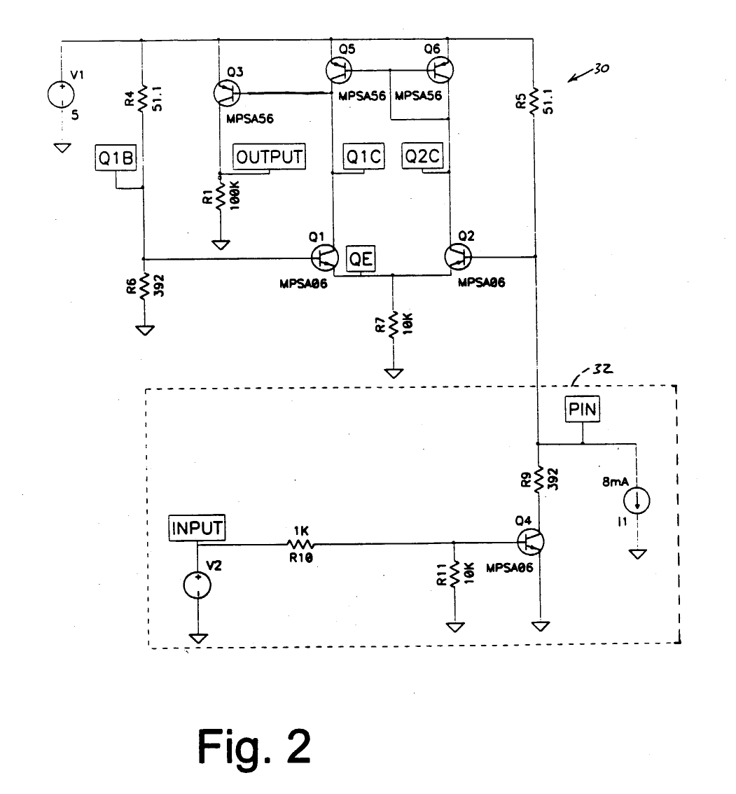

FIG. 2 illustrates a preferred embodiment of a two wire Hall device output detection circuit of the present invention connected to a circuit model of a two wire Hall device. The Hall device output detection circuit is indicated at 30, while the Hall device circuit model is indicated at 32. In the circuit model, V2 represents the Hall voltage. Voltage V2 is connected to the base of transistor Q4 through input resistors R10 and R11. When voltage V2 is sufficient to activate transistor Q4, the device output pin is pulled lower by current through resistor R9 and transistor Q4.

Detection circuit 30 includes a differential amplifier including a pair of bipolar junction transistors Q1, Q2 in a common emitter QE configuration with collector outputs Q1C, Q2C. Common emitter QE is connected through resistor R7 to the common ground. A current mirror includes a pair of bipolar junction transistors Q5, Q6 with collectors connected to the collector outputs of the differential amplifier Q1C, Q2C. The current mirror has a reference side Q6 and an output side Q5. An output stage amplifier includes a bipolar junction transistor Q3 with a base input connected to the output side of the current mirror and a collector output. The collector output of transistor Q3 is connected through resistor R1 to the common ground. Resistors R4 and R6 are connected to base Q1B of transistor Q1, while resistor R5 and the Hall device pin are connected to the base of transistor Q2.

A preferred embodiment of the two wire Hall device output detection circuit operates as follows. When the Hall voltage is insufficient to turn on transistor Q4, current source I1 and resistor R5 determine the voltage at the two wire Hall device output pin connected to the base of transistor Q2. Voltage source V1 and resistors R4 and R6 determine the voltage at the base Q1B of transistor Q1. The differential amplifier made up of the bipolar junction transistor pair Q1, Q2 with common emitter QE has a differential output at collectors Q1C, Q2C. The voltage at Q2C determines the reference current through the current mirror, and the reference current through Q6 is mirrored at Q5. Q3 remains off.

When the Hall voltage increases sufficiently to turn on transistor Q4, the output pin of the Hall device decreases in voltage. The drop in pin voltage results in less current on the reference side of the current mirror, and resultantly less current provided by the output side of the current mirror. In turn, the additional current needed by transistor Q1 is drawn from the base of transistor Q3. Transistor Q3, in turn, quickly saturates, resulting in a rise in output voltage in response to the input Hall voltage.

It is appreciated that FIG. 2 illustrates a preferred embodiment of the two wire Hall device output detection circuit of the present invention connected to a circuit model of a two wire Hall device. The two wire Hall device may take any suitable form and component values may vary in the detection circuit. The differential amplifier also may take any suitable form and use any suitable devices. Similarly, the current mirror may take any suitable form and use any suitable devices. The connection of the current mirror across the differential output of the differential amplifier may be implemented in other ways than that illustrated for the preferred embodiment. For example, PNP transistors may be used for the differential amplifier and NPN transistors used for the current mirror. And similarly, the output stage amplifier may take any suitable form or use any suitable device.

While embodiments of the invention have been illustrated and described, it is not intended that these embodiments illustrate and describe all possible forms of the invention. Rather, the words used in the specification are words of description rather than limitation, and it is understood that various changes may be made without departing from the spirit and scope of the invention.

1. A two wire Hall device output detection circuit comprising:
a differential amplifier including a differential input and a differential output;
a current mirror having a reference side and an output side, the current mirror being connected across the differential output of the differential amplifier; and
an output stage amplifier having an input connected to the output side of the current mirror, and an output.

2. The circuit of claim 1 wherein the differential amplifier includes a pair of bipolar junction transistors in a common emitter configuration with collector outputs.

3. The circuit of claim 2 wherein the current mirror includes a pair of bipolar junction transistors with collectors connected to the collector outputs of the differential amplifier.

4. The circuit of claim 3 wherein the output stage amplifier includes a bipolar junction transistor with a base input and a collector output.

5. In combination with a two wire Hall device, a two wire Hall device output detection circuit comprising:
a differential amplifier including a differential input and a differential output, the differential input being connected across the two wire Hall device;
a current mirror having a reference side and an output side, the current mirror being connected across the differential output of the differential amplifier; and
an output stage amplifier having an input connected to the output side of the current mirror, and an output.

6. The combination of claim 5 wherein the differential amplifier includes a pair of bipolar junction transistors in a common emitter configuration with collector outputs.

7. The combination of claim 6 wherein the current mirror includes a pair of bipolar junction transistors with collectors connected to the collector outputs of the differential amplifier.

8. The combination of claim 7 wherein the output stage amplifier includes a bipolar junction transistor with a base input and a collector output.
